(19) United States
(12) Patent Application Publication
(10) Pub. No.: US 2024/0167193 A1
(43) Pub. Date: May 23, 2024

(54) SYSTEMS AND METHODS FOR COOLING A CHUNK POLYCRYSTALLINE FEEDER

(71) Applicant: GlobalWafers Co., Ltd., Hsinchu (TW)

(72) Inventors: JaeWoo Ryu, Chesterfield, MO (US); SeongSu Park, Chungcheongnam-do (KR); JunHwan Ji, Chungcheongnam-do (KR); Carissima Marie Hudson, St. Charles, MO (US); William Lynn Luter, St. Charles, MO (US)

(21) Appl. No.: 18/515,801

(22) Filed: Nov. 21, 2023

Related U.S. Application Data
(60) Provisional application No. 63/384,625, filed on Nov. 22, 2022.

(51) Int. Cl. C30B 15/24; C30B 15/02; C30B 15/10; C30B 15/20

(52) U.S. Cl. CPC C30B 15/24; C30B 15/02; C30B 15/10; C30B 15/206

(57) ABSTRACT

A crystal ingot puller includes a crucible for holding a crystal melt, a crystal puller housing that defines a growth chamber, and a polycrystalline feed system for supplying chunk polycrystalline to the crucible. The polycrystalline feed system includes a feed tube having an outer sidewall, an inlet end and an outlet end, and a cooling jacket surrounding the outer sidewall of the feed tube at the outlet end of the feed tube. The cooling jacket cools the outlet end during operation of the ingot puller.

### CROSS-REFERENCE TO RELATED APPLICATION

This application claims priority to U.S. Provisional Patent Application No. 63/384,625 filed on Nov. 22, 2022, the entire disclosure of which is incorporated by reference in its entirety.

### FIELD

The field generally relates to the production of silicon ingots, and more specifically, to systems and methods for cooling a chunk polycrystalline feeder of a crystal puller.

### BACKGROUND

Single crystal silicon productivity and crystal cost for a given crucible size and HZ configuration are improved by maximizing a charge size, reducing time of polycrystalline silicon meltdown and enabling multiple recharge capability. The initial meltdown process includes melting of a volume charge stack of polycrystalline within a crucible of the crystal puller and subsequent feeding of additional polycrystalline to the crucible as the initial volume charge stack of polycrystalline is expended.

Chunk or granular type polycrystalline silicon is commonly poured onto the molten silicon in the crucible via a quartz dumper system. Another known polycrystalline feeding method is to drop chunk type poly silicon above the silicon melt using a speed control feeding mechanism having a feed tube. In such a system, the feed tube is made of silicon and has a temperature-driven position limitation of the end of the tube over the melt. In some instances, due to the height of the end of the tube from the melt, silicon dust or crushed particles can be generated, which can negatively impact the crystal growth process. To reduce silicon dust or crushed particle generation, the tube has to be positioned at a closer distance from the surface of the melt. This however can cause damage or melting of the end of the tube. Silicon dust and particles can affect ZD success of crystal growth because they are the major source of LZD issue. Therefore, there is a need to reduce silicon dust or crushed particle generation during feeding of polycrystalline silicon.

This background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, an ingot puller for manufacturing a single crystal ingot includes a crucible for holding a crystal melt, and a puller housing that defines a growth chamber for pulling the ingot from the melt. The crucible is disposed within the growth chamber and a polycrystalline feed system supplies chunk polycrystalline to the crucible. The polycrystalline feed system includes a feed tube having an outer sidewall, an inlet end and an outlet end and, a cooling jacket surrounding the outer sidewall of the feed tube at the outlet end of the feed tube. The cooling jacket cools the outlet end during operation of the ingot puller.

Another aspect is a method of cooling an outlet end of a feed tube of a polycrystalline feed system for adding chunk polycrystalline to a crucible for holding a crystal melt of a crystal puller apparatus. The crystal puller apparatus includes a crystal puller housing that defines a growth chamber for pulling the ingot from the melt with the crucible being disposed within the growth chamber. The method includes supplying a coolant to a cooling jacket surrounding an outer sidewall of the feed tube at the outlet end of the feed tube. The cooling jacket cools the outlet end during operation of the ingot puller. The method further includes lowering the feed tube to a first distance from a top surface of the melt and supplying chunk polycrystalline to the melt.

Various refinements exist of the features noted above in relation to the various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. Again, the brief summary presented above is intended only to familiarize the reader with certain aspects and contexts of the present disclosure without limitation to the claimed subject matter.

### BRIEF DESCRIPTION OF THE DRAWINGS

FIG. 1A is a section view of an ingot puller used to pull a crystal silicon ingot from a silicon melt.

FIG. 1B is a section view of an ingot puller and a feed system used to supply polycrystalline.

FIG. 2A is a section view of a feed tube and cooling jacket in accordance with an embodiment of the present disclosure.

FIG. 2B is a section view of a feed tube and cooling jacket in accordance with an embodiment of the present disclosure.

FIG. 3A is a section view of a polycrystalline feed system and cooling system of the ingot puller of FIG. 1 in an extended feeding position.

FIG. 3B is a section view of a polycrystalline feed system and cooling system of the ingot puller of FIG. 1 in a retracted position.

FIG. 4 is a section view of a bellows assembly of the cooling system of FIG. 3A.

FIG. 5 is a method of cooling an outlet end of a feed tube of a polycrystalline feed system.

Like reference symbols in the various drawings indicate like elements.

### DETAILED DESCRIPTION

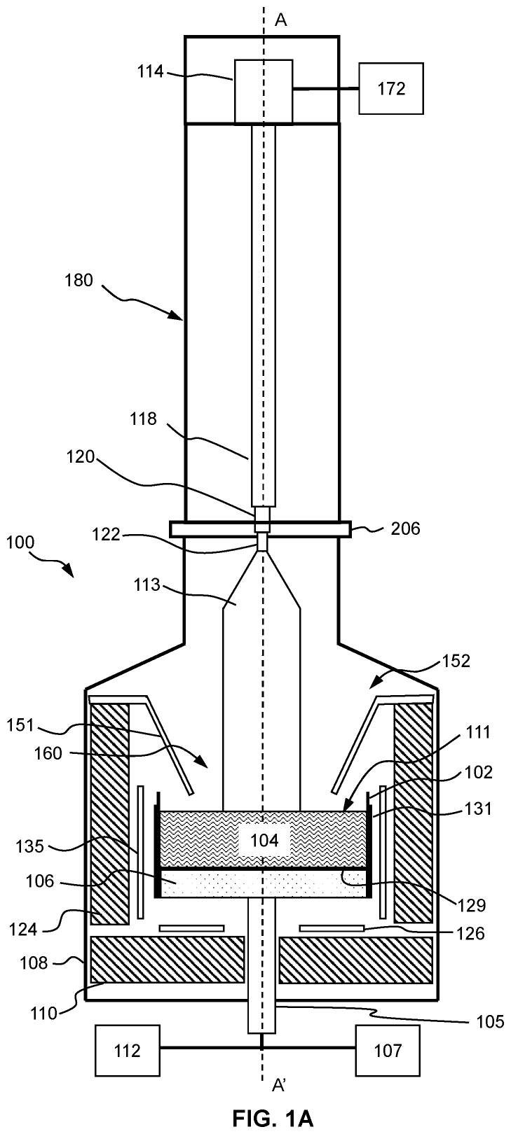

FIG. 1A is a section view of an ingot puller indicated generally at “100” used to pull or grow a crystal ingot from a silicon melt (the puller may be referred to as an ingot or crystal puller). The ingot puller 100 includes a crystal puller housing 108 that defines a growth chamber 152 for pulling an ingot 113 from a melt 104 of silicon. A controller 172 controls operation of the ingot puller 100 and its components. The ingot puller 100 includes a crucible 102 disposed within the growth chamber 152 for holding the melt 104 of molten material such as silicon. The crucible 102 is supported by a susceptor 106.

The crucible 102 includes a floor 129 and a sidewall 131 that extends upward from the floor 129. The sidewall 131 is generally vertical in this embodiment. The floor 129 includes the curved portion of the crucible 102 that extends below the sidewall 131. Within the crucible 102 is a silicon melt 104 having a melt surface 111 (i.e., melt-ingot interface). The susceptor 106 is supported by a shaft 105. The susceptor 106, crucible 102, shaft 105 and ingot 113 have a common longitudinal axis A or “pull axis” A.

A pull chamber 180 is connected to growth chamber 152 to start crystal growth. The pull chamber 180 includes a pulling mechanism 114 for growing and pulling an ingot 113 from the melt 104. Pulling mechanism 114 includes a pulling cable 118, a seed holder or chuck 120 coupled to one end of the pulling cable 118, and a seed crystal 122 attached to the seed holder or chuck 120 for initiating crystal growth. One end of the pulling cable 118 is connected to a pulley (not shown) or a drum (not shown) within the pulling mechanism 114, or any other suitable type of lifting mechanism, for example, a shaft, and the other end is connected to the seed holder or chuck 120 that holds the seed crystal 122. In operation, the seed crystal 122 is lowered to contact the melt 104. The pulling mechanism 114 is operated by a controller to cause the seed crystal 122 to rise. This causes a crystal ingot 113 to be pulled from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. As the ingot grows, the melt 104 is consumed and the height of the melt in the crucible 102 decreases. The crucible 102 and susceptor 106 may be raised to maintain the melt surface 111 at or near the same position relative to the ingot puller 100.

The ingot puller 100 may include an inert gas system to introduce and withdraw an inert gas such as argon from the growth chamber 152. The ingot puller 100 may also include a dopant feed system (not shown) for introducing dopant into the melt 104.

The ingot puller 100 includes bottom insulation 110 and side insulation 124 to retain heat in the puller apparatus 100. In the illustrated embodiment, the ingot puller 100 includes a bottom heater 126 disposed below the crucible floor 129 and a heater 135 and a susceptor 106 that encircles the crucible 102 to maintain the temperature of the melt 104 during crystal growth. The heater 135 is disposed radially outward to the crucible sidewall 131 as the crucible 102 travels up and down the pull axis A. The heater 135 and bottom heater 126 may be any type of heater that allows the heater 135 and bottom heater 126 to operate as described herein. The heaters 135, 126 are suitably resistance heaters. The side heater 135 and bottom heater 126 may be controlled by a control system (not shown) so that the temperature of the melt 104 is controlled within a predetermined range throughout the pulling process.

The ingot puller 100 may also include a reflector 151 (or “heat shield”) disposed within the growth chamber 152 and above the melt 104 which shrouds the ingot 113 during ingot growth. The reflector 151 may be partially disposed within the crucible 102 during crystal growth. The reflector 151 defines a central passage 160 for receiving the ingot 113 as the ingot is pulled by the pulling mechanism 114. The reflector 151 may be a heat shield adapted to retain heat underneath itself and above the melt 104. Other reflector designs and materials of construction (e.g., graphite) may be used without limitation.

According to the Czochralski crystal growth process, a quantity of polycrystalline silicon, or polycrystalline, is charged to the crucible 102 (e.g., charge of 250 kg or more). A variety of sources of polycrystalline silicon may be used including, for example, granular polycrystalline silicon produced by thermal decomposition of silane or a halosilane in a fluidized bed reactor or polycrystalline silicon produced in a Siemens reactor. Once polycrystalline silicon is added to the crucible 102 to form a charge, the charge is heated to a temperature above about the melting temperature of silicon (e.g., about 1412° C.) to melt the charge. In some embodiments, the charge (i.e., the resulting melt) is heated to a temperature of at least about 1425° C., at least about 1450° C. or even at least about 1500° C.

With reference to FIGS. 1B, 2A, 3A and 3B, a polycrystalline feed system 200 introduces a solid-phase polycrystalline charge 202 (referred to as “polycrystalline 202”) through a feed tube 270 and into the crucible 102. As (a full or part of) the initial charge of polycrystalline silicon melts, additional polycrystalline silicon is fed by the polycrystalline feed system 200. As shown in FIG. 1B, the feed tube 270 may be positioned such that polycrystalline is added to the melt 104 within the crucible 102.

The feed tube can be made from a material selected from the group consisting of quartz, silicon, metal oxide, silicon oxide, and suitable metals appropriately cooled or protected such as by coating to prevent contaminating the process, or a combination of these materials.

The polycrystalline 202 that is fed to the crucible 102 by the polycrystalline feed system 200 may be, for example, granular, chunk, chip, or a combination of thereof, and is typically silicon but can include other materials. Chunk polycrystalline typically has a size of between 3 and 45 millimeters (e.g., the largest dimension), and granular polycrystalline typically has a size between 400 and 1400 microns.

The polycrystalline feed system 200 includes at least a hopper 205 and the feed tube 270. Hopper 205 stores the polycrystalline 202 and the hopper 205 feeds the polycrystalline 202 into the feed tube 270 by a gravity feed or vibration system, or other system capable of feeding at a metered feed rate appropriate for the process such as a rotating tube with a helix feature on the interior wall to convey material. In some embodiments, the polycrystalline feed system further includes an interchangeable tray (not shown) and a vibrator (not shown) which vibrates the interchangeable tray such that the polycrystalline 202 from the hopper falls into the feed tube 270. The feed tube 270 receives polycrystalline that exits interchangeable tray due to vibration caused by vibrator. Example components of the polycrystalline feed system 200 are shown and described in U.S. Pat. No. 10,577,717, which is incorporated herein by reference for all relevant and consistent purposes.

The polycrystalline feed system 200 is enclosed within a feed housing 204 and the feed housing 204 is separated from the crystal puller housing 108 by a valve mechanism 206. The valve mechanism 206 may be used to seal the feed tube 270 during periods in which silicon is not being added to the feed tube 270. Both the feed housing 204 and the crystal puller housing 108 are under vacuum conditions. In some embodiments, both the feed housing 204 and the crystal puller housing 108 have a pressure in the range of 10-15 torr.

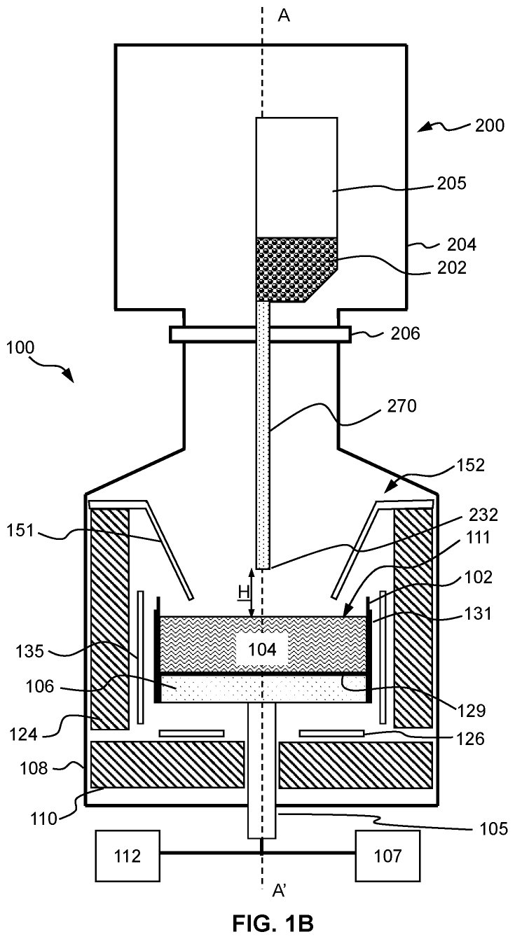

Before adding solid silicon to the initial melt 104, the polycrystalline feed system 200 is docked within the feed housing 204 and the feed tube 270 feed tube 270 is lowered into the growth chamber 152 (e.g., by use of motorized gear system). Silicon is introduced into the feed tube 270 by the polycrystalline feed system 200. Solid silicon passes through the feed tube 270 and is discharged through an outlet 272 (as best shown in FIG. 2) of the feed tube 270. Discharged solid silicon collects on the melt surface 111 and subsequently liquifies into the melt 104. Once the melt 104 is fully formed or replenished, the feed tube 270 is removed from the growth chamber 152.

Referring now to FIGS. 2A and 2B, the feed tube 270 includes an inlet 274 (which may be engaged with a feed tray disposed above the feed tube 270) and an outlet 272. The feed tube 270 includes a conduit 276 through which the polycrystalline 202 travels. The feed tube 270 may include a kick plate 278 disposed below the conduit portion 276 that directs the polycrystalline 202 into the crucible 102.

The conduit 276 of the feed tube 270 may include baffles (not shown) to control the speed of the polycrystalline 202 through the feed tube 270. The silicon feed tube 270, and its components (e.g., kick plate 278, conduit portion 276, guide section 166, and/or tube section 178) are suitably made of silicon or graphite.

As shown in FIG. 1B, the outlet 272 is positioned a height H from the melt surface 111 prior to introducing polycrystalline 202 to the melt 104. The outlet 272 is disposed or positioned close to the melt surface 111 to avoid silicon dust or crushed particles generation as the polycrystalline 202 travels through the conduit portion 276 of the feed tube 270. However, because the temperature at the melt surface 111 is in the range of about 1400° C. to at least 1500° ° C. or higher, the feed tube 270 (and in particular the outlet 272 and conduit portion 276) is prone to thermal damage as the outlet 272 approaches the melt surface 111. Thermal damage includes, but is not limited to, melting and cracking. The height H is thus defined by the distance from the outlet 272 to the melt surface 111 when the feed tube 270 is depositing polycrystalline 202. For the illustrated embodiment, the outlet 272 can extend to the reflector 151, or the height H is approximately 170 mm.

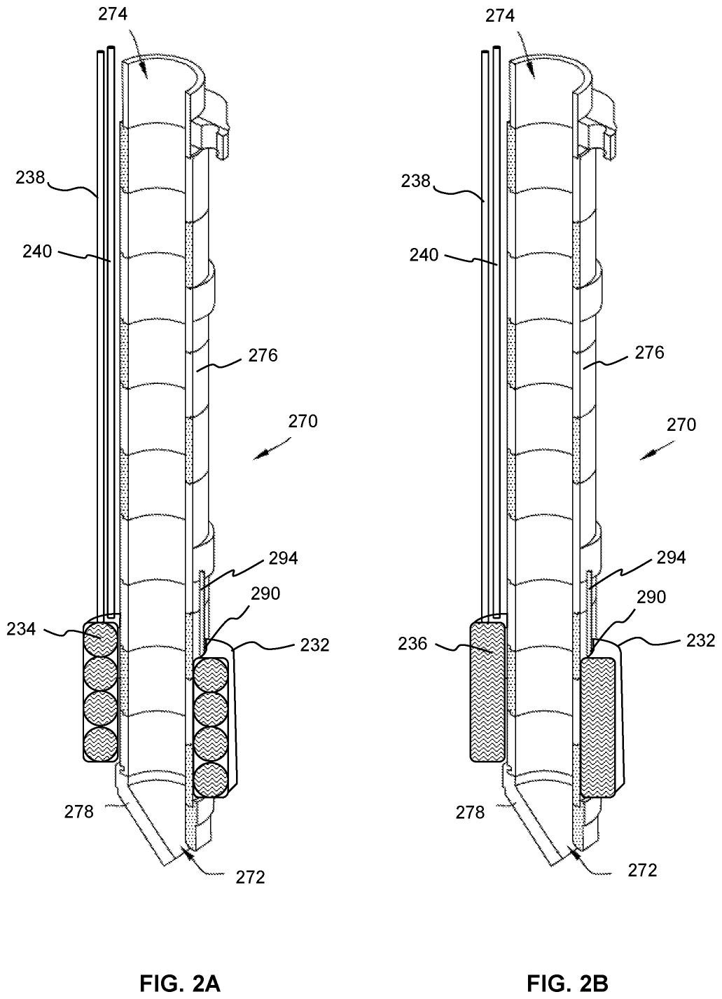

As shown in FIGS. 2A, 2B, 3A and 3B, a cooling system 230 can be attached to the polycrystalline feed system 200 for reducing the temperature of the outlet 272 of the feed tube 270 when the feed tube 270 is depositing polycrystalline 202. The cooling system 230 protects the outlet 272 of the feed tube 270 from the extreme heat in the growth chamber 152. As explained in detail below, the cooling system 230 allows for the outlet 272 of the feed tube 270 to be positioned closer to the melt surface 111 relative to the height H of the outlet 272 without the cooling system 230.

As best shown in FIGS. 3A and 3B, the cooling system 230 includes a fluid source 239 positioned outside from the feed housing 204 and a heat exchanger 232 positioned at or near the outlet 272 of the feed tube 270 such that the heat exchanger 232 fully surrounds the outlet 272, or more specifically, the heat exchanger 232 extends circumferentially around a portion of the feed tube 270 that is at or near the outlet 272. The heat exchanger 232 is suitably positioned near regions that are most susceptible to extreme thermal temperatures due to proximity to the melt surface 111.

The heat exchanger 232 is fluidly connected to the fluid source 239 by a fluid inlet conduit 238 and a fluid outlet conduit 240 defining a cooling circuit as shown in FIGS. 2A and 2B. As shown in FIGS. 3A and 3B, the fluid circuit includes a valve or pump 237 connected to a processor for controlling the flow of fluid. The fluid is a temperature-controlling fluid or coolant and is in thermal communication with the cooling system 230. In the example embodiment, fluid conduits 212 receive fresh fluid from the fluid source 239. The flow rate is maintained generally constant by the pump 237.

The fluid source 239 is suitably a reservoir (not shown) that has a sufficient volume such that the fluid circulated through the reservoir is uniformly cooled. Alternatively, fluid can be partially expelled from the reservoir and fresh fluid can be added to the reservoir. The fluid may be chilled plant water of a relatively constant temperature (e.g., between about 24° C.+/−1ºC and about 35° C.+/−1° C.) that is obtained from the fluid source 239 or other source before entering the cooling system 230. After contact with the heat exchanger 232, the fluid is returned to the fluid source 239 or reservoir.

As shown in FIGS. 2A and 2B, the heat exchanger 232 contacts an outer surface 290 of the feed tube 270 such that the heat exchanger 232 extracts heat from the outer surface of the outlet 272 of the feed tube 270. The heat exchanger 232 can be selected from the group consisting of a cooling jacket, a coiled conduit and a reservoir. Fluid passes through the heat exchanger 232 to promote the transfer of heat from the outer surface 290 of the feed tube 270 to the heat exchanger 232.

As shown in FIG. 2A, the exchanger 232 includes a plurality of coiled tubes 234, and/or a single tube having a plurality of coiled sections, surrounding the outer surface 290 of the feed tube 270 and in contact with the outer surface 290. As shown in FIG. 2B, the heat exchanger 232 is a cooling jacket including a reservoir 236 through which liquid flows through. The heat exchanger 260 can further include a radiation shield (not shown) surrounding the heat exchanger 260. The radiation shield can be a refractory metal such as molybdenum, tantalum, or tungsten. Furthermore, multiple radiation shields can be included to impede the radiant heat flux from the molten silicon

As shown in FIGS. 3A and 3B, in operation, the fluid source 239 circulates fluid through the heat exchanger 232 as the feed tube 270 is lowered into the growth chamber 152 (of FIG. 1). As shown in FIG. 3A, the outlet 272 of the feed tube 270 is lowered to a height H₁ from the surface melt 111. Because the heat exchanger 232 extracts heat from the outlet 272 of the feed tube 270, the height H₁ is less than the height H (as shown in FIG. 1, where the heat exchanger 232 is not included). For the illustrated embodiment, the outlet 272 can extend below the reflector 151 of FIG. 1. Depending on the ingot puller configuration, the height H₁ can be in the range of 50 mm to 150 mm less than the height H (as shown in FIG. 1), where the heat exchanger 232 is not included. In other configurations, the height H₁ is in the range of 50 mm to 250 mm less than the height H.

The height H₁ of the outlet 272 from the surface melt 111 can also be increased or decreased by movement of the shaft 105 and susceptor 106 along the longitudinal axis A. As the melt 104 is depleted and additional polycrystalline 202 is fed into the crucible 102, an island of unmelted polycrystalline temporarily forms on the melt surface 111. The polycrystalline island prevents splashing during feeding, which also protects the outlet 272 from splash damage. This increases the lifetime of the feed tube 270, especially when the outlet 272 is closer to the melt due to the benefit of the heat exchanger 232.

Because the fluid source 239 is external to the feed housing 204, bellows assembly 250 is secured to the feed housing 204 such that a vacuum or low pressure state is maintained within the feed housing 204. The bellows assembly 250 retracts and extends as the feed tube 270 is lowered into the growth chamber 152 (of FIG. 1). As shown in FIG. 3B, the bellows assembly 250 extends by the difference between height H₁ and a height H₂, where the height H₂ is the distance from the outlet 272 when the feed tube 270 is retracted.

The heat exchanger 232 may also be retrofitted onto existing feed systems. By way of example, the heat exchanger 232 can be affixed onto the outer surface 290 of a feed tube and connected to an external reservoir and valve, or pump. As shown in FIGS. 2A and 2B, the outer surface 290 can include stainless steel bars 294 as an attachment fixture to which the heat exchanger 232 can be attached to. The stainless-steel bars 294 can have bracket to hold heat exchanger 232. After the heat exchanger 232 is affixed to the stainless steel bars 294, fluid conduits (238, 240) are connected to heat exchanger 232.

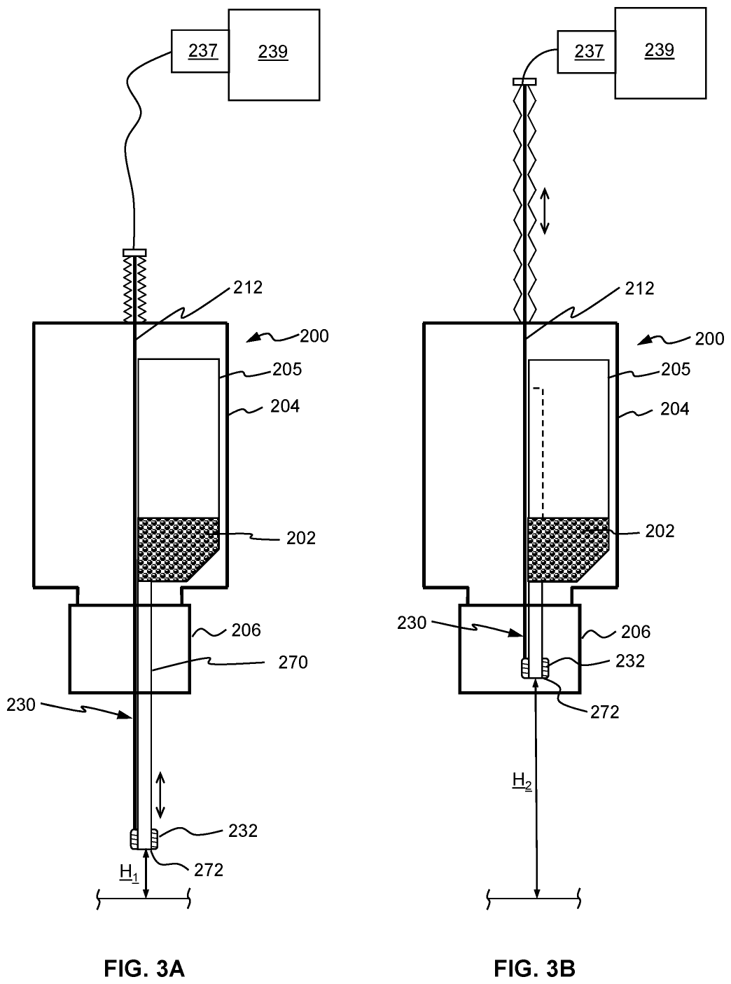

As shown in FIG. 4, the bellows assembly 250 comprises multiple bellows sections 252 connected in series. Each bellows section 252 includes a top plate 254 and a bottom plate 256. In some embodiments, the top-most bellows sections 252 are bolted together. In some embodiments, the bellows assembly 250 further comprises a support rail 258 for translating the bellows assembly 250 between extensions and compressions.

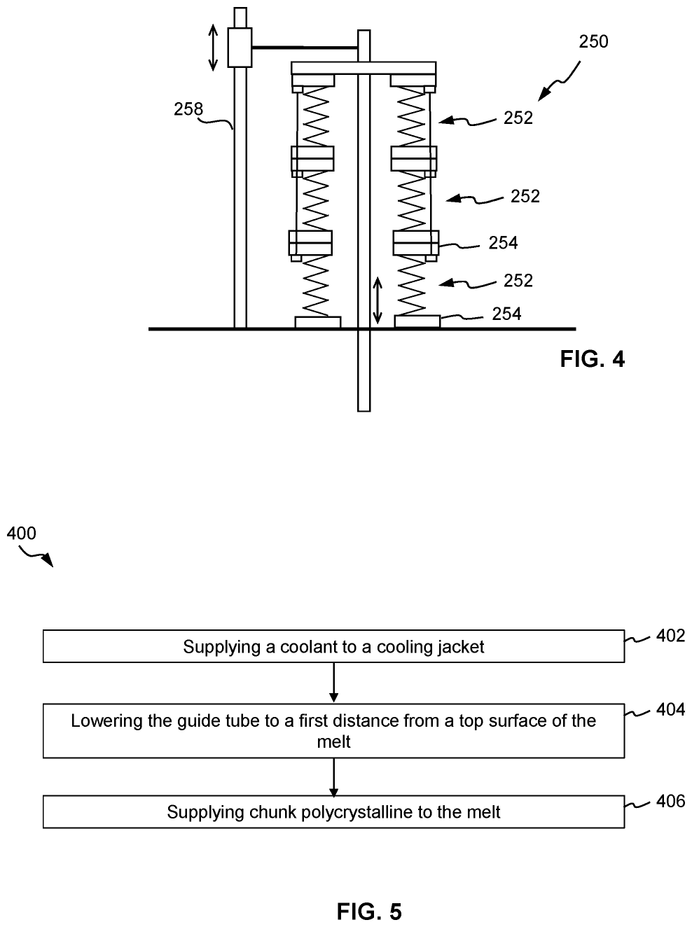

A method 400 for cooling an outlet end of a feed tube of a polycrystalline feed system is illustrated in FIG. 5. The method 400 includes supplying 402 a coolant to a cooling jacket, lowering 404 the feed tube to a first distance from a top surface of the melt; and supplying 406 chunk polycrystalline to the melt.

The examples disclosed above enable the feed tube to be positioned closer to the surface of the melt within the crystal puller (as compared to the prior art), thereby reducing the impact of silicon dust or crushed particle generation. The outlet of the feed tube is less prone to thermal damage. The embodiments also enable cooling an outlet of the feed tube, for example by a heat exchanger abutting the outlet. By cooling the outlet, the feed tube can be placed closer to a surface melt, thereby also reducing dust and particle generation. Positioning the outlet of the feed tube closer to the surface of the melt makes the outlet more prone to splash from the melt, however because an island of unmelted polycrystalline is formed on the surface of the melt during feeding, splash damage is minimized. This allows for the crucible to be moved closer to the outlet of the feed tube, further reducing the height between the surface of the melt and the outlet, thereby further reducing dust and particle generation.

When introducing elements of the present disclosure or the embodiment (s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, “down”, “up”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An ingot puller for manufacturing a single crystal ingot, the ingot puller comprising:
a crucible for holding a crystal melt;
a crystal puller housing that defines a growth chamber for pulling the ingot from the melt, the crucible being disposed within the growth chamber; and
a polycrystalline feed system for supplying chunk polycrystalline to the crucible, the polycrystalline feed system comprising:
a feed tube having an outer sidewall, an inlet end and an outlet end; and
a cooling jacket surrounding the outer sidewall of the feed tube at the outlet end of the feed tube, the cooling jacket for cooling the outlet end during operation of the ingot puller.

2. The ingot puller as set forth in claim 1, wherein operation of the cooling jacket reduces a temperature of the outlet end of the feed tube.

3. The ingot puller as set forth in claim 2, wherein the outlet end of the feed tube has a first temperature when the cooling jacket is operating and a second temperature when the cooling jacket is not operating, the first temperature being less than the second temperature.

4. The ingot puller as set forth in claim 3, wherein the first temperature is less than 900° C.

5. The ingot puller as set forth in claim 4, wherein operating the outlet end of the feed tube at the second temperature causes damage to the outlet end.

6. The ingot puller as set forth in claim 2, wherein the outlet end of the feed tube is positioned at a first distance from a top surface of the melt when the cooling jacket is operating, and the outlet end of the feed tube is positioned a second distance from the top surface of the melt when the cooling jacket is not operating, the first distance is less than the second distance.

7. The ingot puller as set forth in claim 6, wherein the first distance reduces splash of the melt from falling chunk polycrystalline, reduces damage to a reflector of the ingot puller, and reduces polycrystalline dust generation.

8. The ingot puller as set forth in claim 4, wherein the outlet end of the feed tube is positioned below a reflector of the ingot puller when the cooling jacket is operating.

9. The ingot puller as set forth in claim 1, wherein the feed tube is made from a material selected from the group consisting of quartz, silicon, metal oxide, silicon oxide, and stainless steel coated with silicon.

10. The ingot puller as set forth in claim 1 further comprising a chute to supply chunk polycrystalline to the feed tube, the chute connected to the inlet end of the feed tube.

11. The ingot puller as set forth in claim 1 further comprising a coolant reservoir in fluid communication with the cooling jacket.

12. The ingot puller as set forth in claim 11, wherein the coolant reservoir is connected to the cooling jacket by a stainless-steel conduit.

13. The ingot puller as set forth in claim 12, wherein the conduit is parallel to the feed tube and is raised and lowered with the feed tube.

14. The ingot puller as set forth in claim 13, wherein the conduit is in near-vacuum and the reservoir is in normal atmospheric pressure, wherein a bellows assembly extending outward from the ingot puller is raised and lowered with the feed tube, the bellows assembly in near-vacuum.

15. The ingot puller as set forth in claim 1, wherein the cooling jacket is selected from the group consisting of a stainless-steel coil, a copper coil with a stainless-steel envelope, and a copper coil with a stainless-steel envelope.

16. The ingot puller as set forth in claim 1 wherein a kick plate is disposed adjacent to the outlet end of the feed tube, the kick plate extending partially across an inner diameter of the feed tube.

17. A method of cooling an outlet end of a feed tube of a polycrystalline feed system for adding chunk polycrystalline to a crucible for holding a crystal melt of a crystal puller apparatus, the crystal puller apparatus including crystal puller housing that defines a growth chamber for pulling an ingot from the melt, the crucible being disposed within the growth chamber, the method comprising:
supplying a coolant to a cooling jacket, the cooling jacket surrounding an outer sidewall of the feed tube at the outlet end of the feed tube, the cooling jacket for cooling the outlet end during operation of the crystal puller;
lowering the feed tube to a first distance from a top surface of the melt; and
supplying chunk polycrystalline to the melt.

18. The method as set forth in claim 17, wherein the outlet end of the feed tube is positioned a second distance from the top surface of the melt when the cooling jacket is not supplied with the coolant, the first distance is less than the second distance.

19. The method as set forth in claim 17, wherein the outlet end of the feed tube has a first temperature when the cooling jacket is supplied with the coolant, and a second temperature when the cooling jacket is not supplied with the coolant, the first temperature less than the second temperature.

20. The method as set forth in claim 19, wherein the first temperature is less than 900° C. and the second temperature damages the outlet end of the feed tube.
